(19) United States
(12) Patent Application Publication
(10) Pub. No.: US 2010/0025081 A1
(43) Pub. Date: Feb. 4, 2010

(54) WIRING SUBSTRATE AND ELECTRONIC COMPONENT DEVICE

(76) Inventors: Tadashi Arai, Nagano (JP); Toshio Kobayashi, Nagano (JP)

Correspondence Address: KRATZ, QUINTOS & HANSON, LLP, 1420 K Street, N.W., Suite 400, WASHINGTON, DC, 20005, US

(21) Appl. No.: 12/492,560

(22) Filed: Jun. 26, 2009

(30) Foreign Application Priority Data
Jul. 30, 2008 (JP) 2008-196449

(51) Int. Cl. H05K 1/16; H05K 1/11; H05K 1/09

(52) U.S. Cl. 174/251; 174/255; 174/260; 174/261

(57) ABSTRACT

A wiring substrate includes a frame-shaped reinforcing plate in which an opening portion is provided in a center portion, an interposer arranged in the opening portion of the reinforcing plate and having such a structure that a wiring layer connected mutually via a through electrode is formed on both surface sides of a substrate respectively, a resin portion filled between a side surface of the interposer and a side surface of the opening portion of the reinforcing plate, and coupling the interposer and the reinforcing plate, and an n-layered (n is an integer of 1 or more) lower wiring layer connected the wiring layer on the lower surface side of the interposer to extend from the interposer to an outer area.

### CROSS-REFERENCE TO RELATED APPLICATIONS

This application is based on and claims priority of Japanese Patent Application No. 2008-196449 filed on Jul. 30, 2008, the entire contents of which are incorporated herein by reference.

### BACKGROUND OF THE INVENTION

1. Field of the Invention

The present invention relates to a wiring substrate and an electronic component device and, more particularly, a wiring substrate on which an electronic component such as a semiconductor chip, or the like is mounted and an electronic component device constructed by mounting an electronic component on the wiring substrate.

2. Description of the Related Art

In the prior art, there is a wiring substrate on which an electronic component such as a semiconductor chip, or the like is mounted (electronic component mounting package). As such wiring substrate, there is a coreless wiring substrate from which a core substrate as a supporting base material is omitted in order to attain the thin type. The coreless wiring substrate is manufactured by forming a build-up wiring layer on a temporary substrate, and then removing or peeling the temporary substrate.

As the technology related with the above prior art, in Patent Literature 1 (Patent Application Publication (KOKAI) 2003-289120), it is set forth that a thin film wiring substrate for mounting a semiconductor chip is obtained by forming a multilayer thin film wiring on both front and back surfaces of a base substrate, then cutting/separating the base substrate into the front surface side and the back surface side, and then removing the base substrate.

Also, in Patent Literature 2 (Patent Application Publication (KOKAI) Hei-2-322030), it is set forth that, in a multilayer wiring substrate in which thin film wiring conductor layers are stacked on an insulating substrate, a warp of the insulating substrate can be prevented by embedding a frame-shaped metal layer to a peripheral portion of an inside in the insulating substrate such that conductor layers which are formed in the inside of the insulating substrate are surrounded.

In the above coreless wiring substrate in the prior art, such a problem exists that because a thickness thereof is thin, rigidity is small and a warp is ready to occur. In particular, during a heating process applied to mount a semiconductor chip, a thermal stress is caused due to a difference in coefficient of thermal expansion between the semiconductor chip and the wiring substrate, and then a warp of the wiring substrate is ready to occur due to this thermal stress.

### SUMMARY OF THE INVENTION

It is an object of the present invention to provide a wiring substrate capable of preventing occurrence of a warp upon mounting a semiconductor chip, or the like, even when the thin wiring substrate without the core substrate is used, and an electronic component device using the same.

The present invention is concerned with a wiring substrate, which includes a frame-shaped reinforcing plate in which an opening portion is provided in a center portion; an interposer arranged in the opening portion of the reinforcing plate, and having such a structure that a wiring layer connected mutually via a through electrode is formed on both surface sides of a substrate respectively; a resin portion filled between a side surface of the interposer and a side surface of the opening portion of the reinforcing plate, and coupling the interposer and the reinforcing plate; and an n-layered (n is an integer of 1 or more) lower wiring layer formed under the interposer and the reinforcing plate, and connected the wiring layer on the lower surface side of the interposer to extend from the interposer to an outer area.

In the wiring substrate of the present invention, the frame-shaped reinforcing plate is coupled to the periphery of the interposer (the thin silicon interposer, or the like) by the resin portion. Accordingly, even when a thickness of the interposer is reduced and its rigidity becomes weak, sufficient rigidity of the interposer can be obtained.

Therefore, in particular, even though a heat is applied and a stress is caused in a series of steps in which the electronic component (the semiconductor chip, or the like) is mounted on the interposer in the wiring substrate, such a situation can be prevented that a warp of the interposer occurs. Accordingly, yield and reliability of the electronic component device which is constructed by mounting the electronic component on the wiring substrate can be improved.

Also, the n-layered (n is an integer of 1 or more) lower wiring layer (preferably the multilayer wiring layer), which is connected to the wiring layer on the lower surface side of the interposer and extends from the interposer to the outside area, is formed under the interposer and the reinforcing plate. Then, the wiring pitch of the lower wiring layer is set wider than the wiring pitch of the interposer, and thus the wiring pitch of the interposer is transformed.

In this manner, the pad pitch of the electronic component is transformed by using the interposer and the lower wiring layer, and then the external connection terminals provided on the lower wiring layer are connected to the mounting substrate (the motherboard, or the like).

As explained above, in the present invention, even when the thin wiring substrate without the core substrate is used, occurrence of a warp can be prevented, and reliability can be improved.

### BRIEF DESCRIPTION OF THE DRAWINGS

FIGS. 1A and 1B are sectional views showing a method of manufacturing an interposer built in a wiring substrate according to an embodiment of the present invention;

FIG. 2 is a plan view showing a state of a copper plate acting as a reinforcing plate of the wiring substrate according to the embodiment of the present invention, and a sectional view showing a section taken along I-I in the plan view;

FIG. 3 is a sectional view (#1) showing a method of manufacturing a wiring substrate according to the embodiment of the present invention;

FIG. 4 is a sectional view (#2) showing the method of manufacturing the wiring substrate according to the embodiment of the present invention;

FIG. 5 is a sectional view (#3) showing the method of manufacturing the wiring substrate according to the embodiment of the present invention;

FIG. 6 is a sectional view (#4) showing the method of manufacturing the wiring substrate according to the embodiment of the present invention;

FIG. 7 is a sectional view (#5) showing the method of manufacturing the wiring substrate according to the embodiment of the present invention;

FIG. 8 is a sectional view and a plan view showing the wiring substrate according to the embodiment of the present invention; and

FIG. 9 is a sectional view showing an electronic component device according to the embodiment of the present invention.

### DETAILED DESCRIPTION OF THE PREFERRED EMBODIMENTS

An embodiment of the present invention will be explained with reference to the accompanying drawings hereinafter.

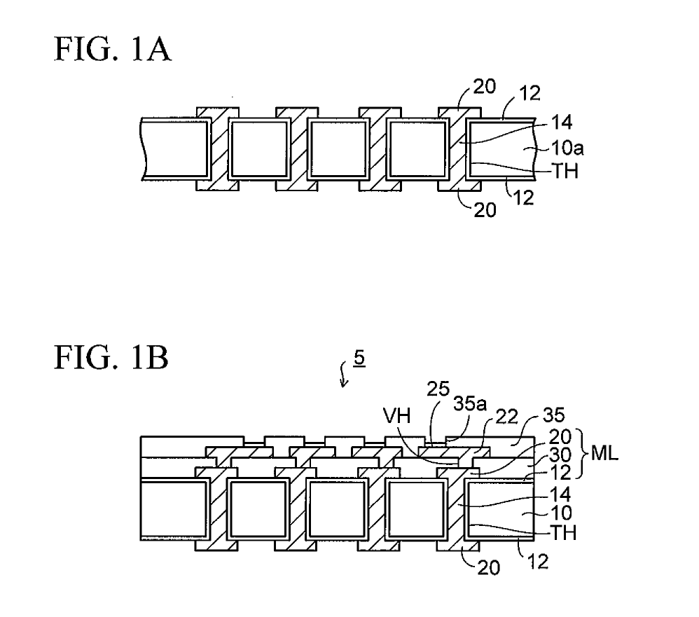

FIGS. 1A and 1B are sectional views showing a method of manufacturing an interposer built in a wiring substrate according to an embodiment of the present invention. At first, a method until a sectional structure shown in FIG. 1A is obtained will be explained hereunder. First, a thickness of a silicon wafer 10a is reduced to about 200 μm by grinding the silicon wafer 10a by using the grinder.

Then, a mask (not shown) in which opening portions are provided is formed on the silicon wafer 10a. Then, through holes TH are formed by penetration-processing the silicon wafer 10a to the thickness direction by means of the anisotropic dry etching (RIE, or the like) through the opening portions in the mask. Then, the mask is removed. The fine through holes TH whose diameter is 20 to 30 μm can be easily formed by using the anisotropic dry etching.

Then, a silicon oxide layer is formed on inner surfaces of the through holes TH and both surface sides of the silicon wafer 10a by the thermal oxidation method or the CVD method, thus an insulating layer 12 is obtained Then, a first wiring layers 20 made of copper, or the like and connected mutually via through electrodes 14 in the through holes TH are formed on both surface sides of the silicon wafer 10a respectively.

As an example of a method of forming the first wiring layers 20 and the through electrodes 14, first, a plating power feeding sheet (not shown) is arranged on the lower surface side of the silicon wafer 10a via a resist (not shown) in which opening portions corresponding to the first wiring layers 20 are provided. Then, by means of the electroplating, the first wiring layers 20 arranged to the lower side are formed in the opening portions in the resist and also the through electrodes 14 are filled in the through holes TH. Then, the first wiring layers 20 connected to the through electrodes 14 is formed on the upper surface side of the silicon wafer 10a by the semi-additive process, or the like.

Then, as shown in FIG. 1B, an interlayer insulating layer 30 is formed on the first wiring layers 20 and the insulating layer 12 on the upper surface side of the silicon wafer 10a. As the interlayer insulating layer 30, a silicon oxide layer formed by the CVD method is preferably employed.

Then, a resist (not shown) in which opening portions are provided is formed on the interlayer insulating layer 30. Then, the interlayer insulating layer 30 is processed by the anisotropic dry etching (RIE, or the like) through the opening portions in the resist. Thus, via holes VH reaching the first wiring layer 20 are formed. The fine via holes whose via pitch is 10 to 30 μm (representative value: 25 μm) can be formed by using the anisotropic dry etching.

Then, second wiring layers 22 connected to the first wiring layers 20 via the via holes VH (via conductor) are formed on the interlayer insulating layer 30. The second wiring layers 22 are formed by forming a metal layer (copper, or the like) by the sputter method, and then patterning the metal layer by means of the photolithography and the etching. A line (L): space (S) of the second wiring layers 22 can be set to 1 μm: 1 μm to 10 μm: 10 μm.

For example, by patterning the copper layer whose thickness is about 3 μm by means of the photolithography and the wet etching, the fine second wiring layers 22 whose line (L): space (S) is about 3 μm: 3 μm can be formed.

Then, a solder resist 35 in which opening portions 35a are provided on connection portions of the second wiring layers 22 is formed. Then, a contact layer 25 is formed by forming sequentially nickel (Ni)/gold (Au) plating layers on the connection portions of the second wiring layers 22. Otherwise, a copper post may be embedded up to top portions of the opening portions 35a in the solder resist 35 by the plating, and then a contact layer (Ni/Au layer) may be formed thereon.

Then, the silicon wafer 10a is cut so that individual chip mounting area is obtained. Accordingly, the silicon wafer 10a is divided into individual silicon substrate 10. As a result, individual interposer 5 employed in the wiring substrate in the present embodiment is obtained.

In the present embodiment, a mode in which the interposer 5 has a two-layered multilayer wiring layer ML (wiring layers 20, 22) on its upper surface side is illustrated. Only the first wiring layers 20 may be formed as a single layer on the upper surface of the interposer 5, or an n-layered (n is an integer of 2 or more) multilayer wiring layer may be provided. That is, the number of stacked wiring layers of the interposer 5 can be set arbitrarily. Also, the multilayer wiring layer having any number of stacked layers and connected to the first wiring layers 20 may be formed on the lower surface side of the silicon substrate 10.

In the interposer 5 according to the present embodiment, the silicon wafer 10a is employed as the substrate, and the wafer processes including the thin film process such as the sputter method, the CVD method, or the like, the microfabrication process made by the photolithography and the etching, and the like are applied. Therefore, the high-density multilayer wiring layer ML including the fine wiring layers 20, 22 and the fine via holes VH, as described above, can be easily formed. As a result, the interposer 5 according to the present embodiment can be employed as the wiring substrate on which the high-performance semiconductor chip is mounted.

Here, as described later, the semiconductor chip is mounted on the interposer 5. Therefore, from a viewpoint of preventing a warp by setting a coefficient of thermal expansion equally between the semiconductor chip (silicon) and the interposer 5, it is preferable that the silicon substrate 10 should be employed as the substrate of the interposer 5.

In the case where a difference in coefficient of thermal expansion between the semiconductor chip (coefficient of thermal expansion (CTE) of silicon: about 3 ppm/° C.) and the interposer 5 does not become an issue, various substrates which are flat and can be made thin type, such as a ceramic substrate (coefficient of thermal expansion (CTE): about 7 ppm/° C.), and the like, may be employed instead of the silicon substrate 10.

Also, the similar multilayer wiring layer (build-up wiring layer) may be formed on the thin resin substrate such as a glass epoxy resin, or the like. In this case, the via holes are formed by the laser and the wiring layers are formed by the semi-additive process, or the like, and as a result, a pitch in the wirings and the vias is increased large rather than the case where the silicon wafer is employed. Also, the first wiring layers on both surface sides may be connected mutually via through hole plating layers (through electrodes) provided in the inner walls of the through holes in the substrate, and the remained slit in the through holes may be filled with a resin.

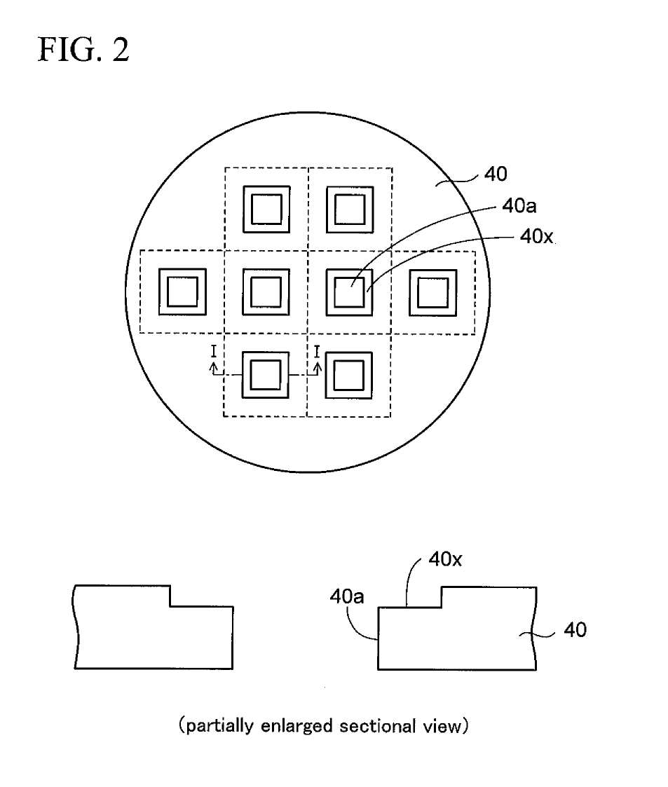

Next, a method of manufacturing the wiring substrate in the present embodiment will be explained hereunder. One of features of the present embodiment resides in that rigidity of the interposer 5 is reinforced by coupling a reinforcing plate to the periphery of the thin interposer 5 by the resin portion. As shown in FIG. 2, first, a copper plate 40 (reinforcing plate) in which a plurality of opening portions 40a are provided to pass through in the thickness direction is prepared. A stepped portion 40x is provided on an upper portion of a side surface of each opening portion 40a along its periphery with a ring shape, and a side surface of the opening portion 40a constitutes a stepped structure (partially enlarged sectional view of FIG. 2 (sectional view taken along I-I in the plan view)).

As a method of forming such opening portions 40a in the copper plate 40, first, a first mask (resist, or the like) (not shown) in which a plurality of opening portions are provided is formed on the copper plate 40. Then, recess portions are formed by applying the wet etching to the copper plate 40 up to the halfway position of thickness through the opening portions.

Then, the first mask is removed, and then a second mask in which an opening portion having a smaller area than the recess portion is provided in center portions of the recess portions respectively is formed. Then, the copper plate 40 is penetration-processed in the thickness direction through the opening portions by the wet etching. Accordingly, the opening portions 40a a side surface of each of which is formed like a stepped shape are formed in the copper plate 40.

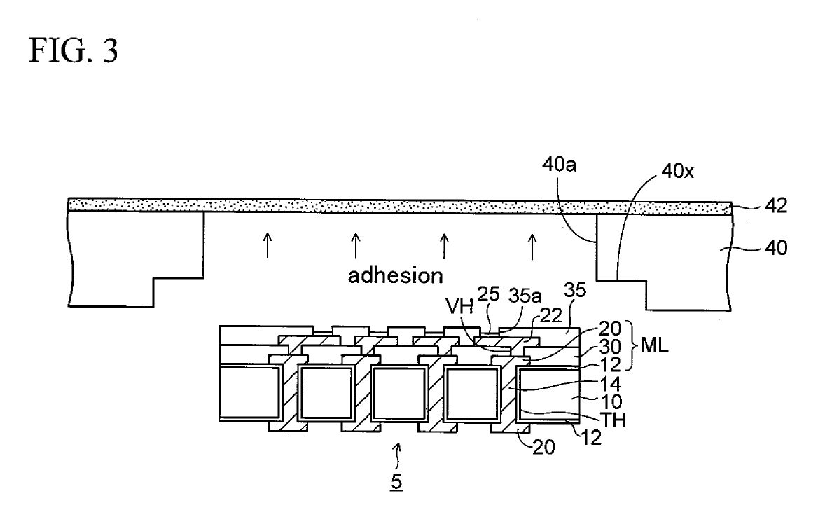

Then, as shown in FIG. 3, the copper plate 40 in FIG. 2 in which the opening portions 40a are provided is turned upside down, and then an adhesive layer 42 is adhered on an upper surface (back surface in FIG. 2) of the copper plate 40. Accordingly, the adhesive layer 42 is arranged on the upper side (bottom surface) in the opening portions 40a in the copper plate 40. Then, the surface of the multilayer wiring layer ML of the interposer 5 described above is arranged on the adhesive layer 42 arranged on the upper side (bottom surface) of the opening portions 40a in the copper plate 40, and is adhered onto the adhesive layer 42.

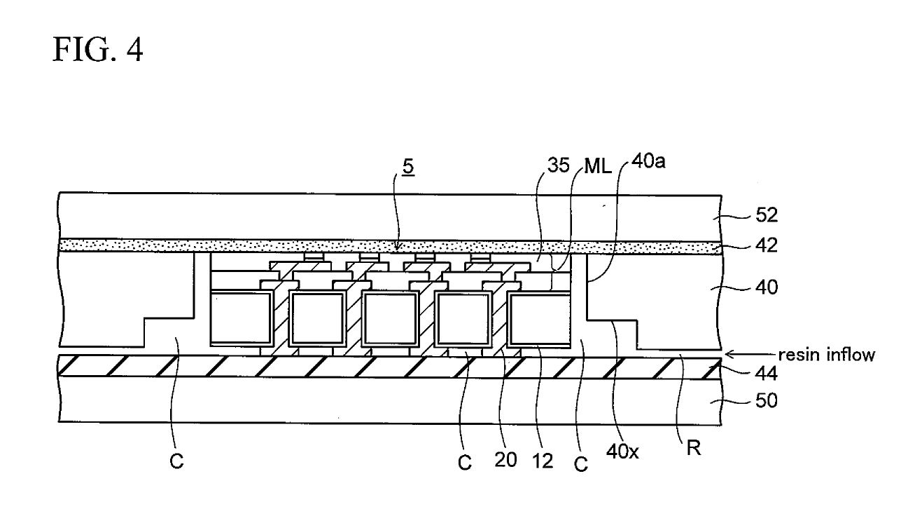

Then, as shown in FIG. 4, the copper plate 40 and the interposer 5 are arranged between a lower mold 50 and an upper mold 52 of the molding equipment in a state that a protection film 44 (Teflon (registered trademark) film, or the like) is arranged on the lower surface sides of the copper plate 40 and the interposer 5 in FIG. 3.

In this manner, the copper plate 40 and the interposer 5 are put between the lower mold 50 and the upper mold 52, thereby a cavity C in which a resin is filled is provided between a side surface of the interposer 5 and side surfaces of the opening portion 40a of the copper plate 40 and between the protection film 44 and a lower surface (insulating layer 12) of the interposer 5. Also, a resin inflow portion R is constructed between the lower mold 50 (protection film 44) and the lower surface of the copper plate 40.

In the upper surface side (the multilayer wiring layer ML side) of the interposer 5, the upper surface of the solder resist 35 is adhered to the adhesive layer 42. Thus, the resin does not flow into the upper surface side of the interposer 5. Also, in the lower surface side of the interposer 5, the lower surfaces of the first wiring layers 20 are adhered to the protection film 44. Thus, the resin does not flow into the lower surface side of the first wiring layers 20, but the resin flows into spaces between a plurality of first wiring layers 20.

Then, the melted resin is caused to flow into the cavity C through the resin inflow portion R. Then, the resin pushed into the cavity C is cured by applying a heat treatment. As the resin, an epoxy resin in which inorganic particles such as silica, or the like are contained (e.g., silica content: 70 to 80%) is preferably employed. Then, the upper mold 52 and the lower mold 50 are removed from the interposer 5 and the copper plate 40, and the adhesive layer 42 and the protection film 44 are peeled and removed.

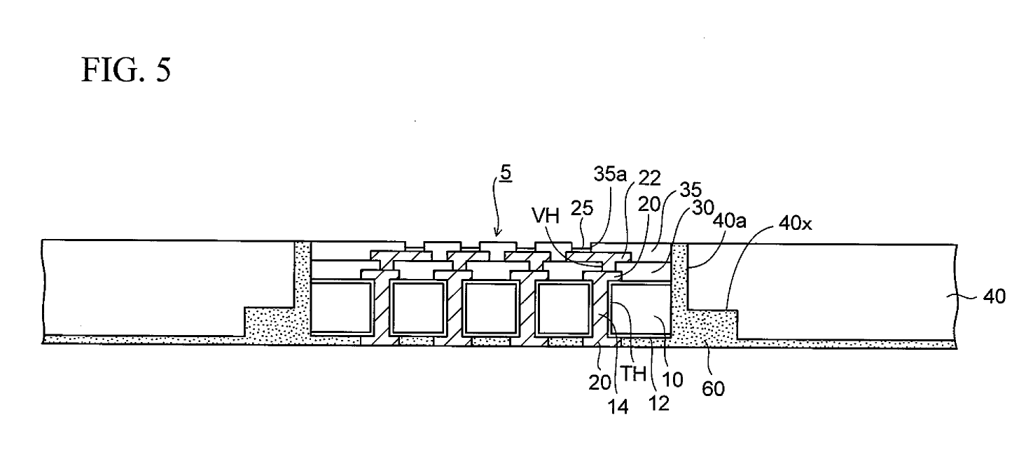

Accordingly, as shown in FIG. 5, a resin portion 60 is formed in the cavity C (FIG. 4) around the interposer 5, and thus the interposer 5 is adhered to the copper plate 40 by the resin portion 60 and is coupled thereto. That is, the interposer 5 is embedded in the resin portion 60 provided in the opening portion 40a of the copper plate 40, and is formed with the copper plate 40 integrally, and thus the interposer 5 whose rigidity is weak is reinforced by the copper plate 40.

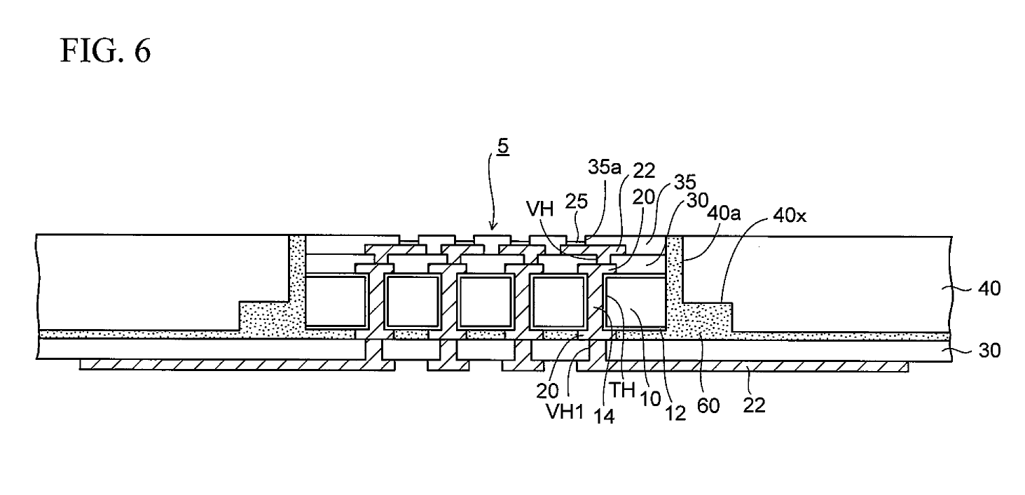

Next, a method of forming the build-up wiring layer (lower wiring layer) connected to the first wiring layers 20 on the lower surface side (opposite side to the multilayer wiring layer ML) of the interposer 5 will be explained hereunder. As shown in FIG. 6, first, the interlayer insulating layer 30 is formed by pasting a resin film on the lower surface sides of the interposer 5 and the copper plate 40, or the like. Then, first via holes VH1 reaching the first wiring layers 20 are formed by processing the interlayer insulating layer 30 by means of the laser, or the like.

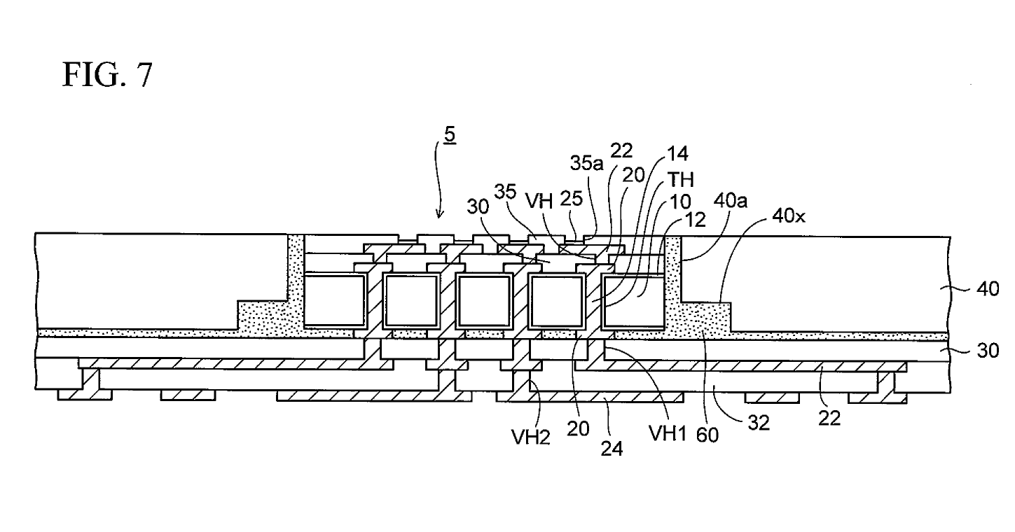

Then, the second wiring layers 22 connected to the first wiring layers 20 on the lower surface side of the interposer 5 via the first via holes VH1 (via conductors) are formed on the interlayer insulating layer 30 (under the interlayer insulating layer 30 in FIG. 6) by the semi-additive process, or the like. Then, as shown in FIG. 7, a second interlayer insulating layer 32 is formed on the second wiring layers 22 (under the second wiring layer 22 in FIG. 7), and then second via holes VH2 reaching the second wiring layers 22 are formed in the second interlayer insulating layer 32. Then, a third wiring layers 24 connected to the second wiring layers 22 via the second via holes VH2 (via conductors) are formed on the second interlayer insulating layer 32 (under the second interlayer insulating layer 32 in FIG. 7).

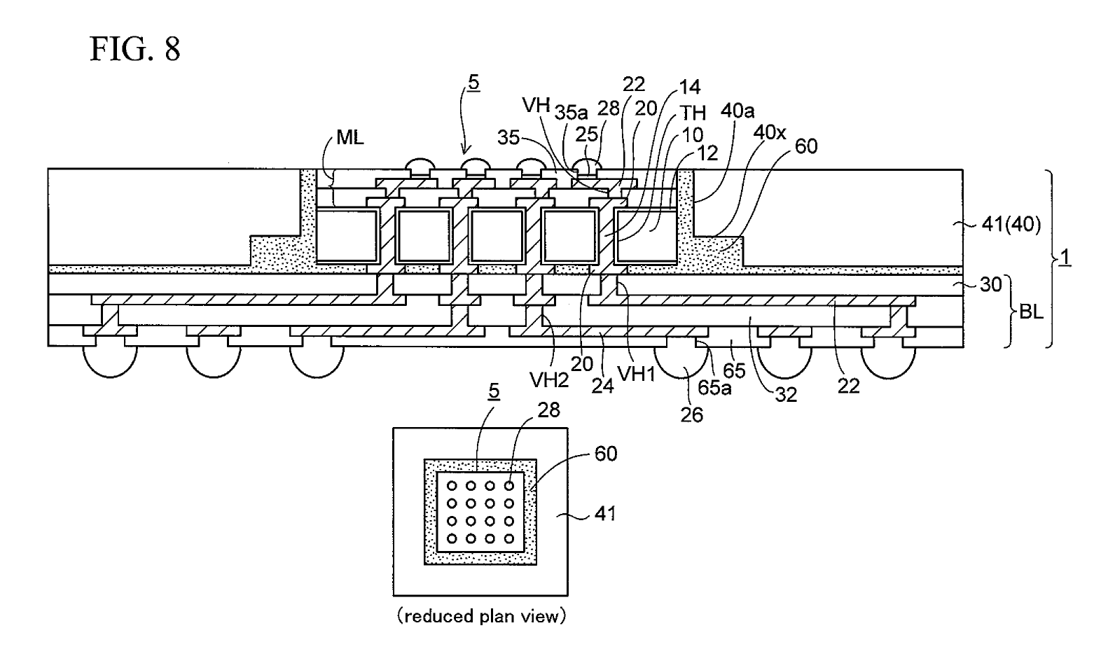

Then, as shown in FIG. 8, a solder resist 65 in which opening portions 65a are provided on connection portions of the third wiring layers 24 (under the third wiring layers 24 in FIG. 8) is formed. Then, contact layers (not shown) are formed in the connection portions of the third wiring layers 24 by forming nickel/gold plating layers, and then external connection terminals 26 are provided by mounting solder balls on the third wiring layers 24, or the like.

Accordingly, build-up wiring layers BL (lower wiring layers) connected to the first wiring layers 20 of the interposer 5 are formed on the lower side of the interposer 5 and the copper plate 40 (opposite side to the multilayer wiring layer ML in the interposer 5). The build-up wiring layers BL are arranged to extend from the first wiring layers 20 of the interposer 5 to the outer areas in a radial fashion respectively, and the external connection terminals 26 are arranged in the outside areas of the interposer 5.

A line (L): space (S) of the build-up wiring layers BL, which are connected to the first wiring layers 20 on the lower surface of the interposer 5, is set within a range of 100 μm: 100 μm to 300 μm: 300 μm. That is, a wiring pitch of the build-up wiring layers BL is set wider than a wiring pitch of the wiring layers (20, 22) of the interposer 5. In this manner, the pitch is transformed such that the wiring pitch of the wiring layers (20, 22) of the interposer 5 is expanded by the build-up wiring layers BL.

In this case, the two-layered wiring layers 22, 24 connected to the first wiring layers 20 on the lower surface side of the interposer 5 are illustrated as the build-up wiring layers BL. The number of stacked layers can be set arbitrarily, and the n-layered (n is an integer of 1 or more) build-up wiring layers can be formed.

Also, the stepped portion 40x is provided to the lower portion of the side surface of the opening portion 40a in the copper plate 40, thereby a diameter of the lower part of the opening portion 40a in the copper plate 40 is set larger than a diameter of the upper part thereof. As a result, even though a thermal stress is caused in forming the build-up wiring layers BL, a stress applied to the resin portion 60 near the lower part of the opening portion 40a can be dispersed and it can be prevented that a crack occurs in the resin portion 60.

Here, there is no necessity that the stepped portion 40x of the opening portion 40a in the copperplate 40 should always be provided. When a failure such as a crack, or the like is not caused in the resin portion 60, the opening portion 40a may be formed into the straight shape.

Then, solder bumps 28 are formed on the contact layers 25 of the uppermost second wiring layers 22 of the multilayer wiring layer ML in the interposer 5.

Upon forming the build-up wiring layer BL, the build-up wiring layer BL is formed simultaneously to each interposer 5 respectively in a state that the interposer 5 is arranged in a plurality of opening portions 40a in the copper plate 40 respectively. Then, the copper plate 40 is cut so that individual wiring substrate is obtained at predetermined timings (along a broken line in the plan view in FIG. 2), and thus the copper plate 40 acts as a reinforcing plate 41 of each interposer 5.

With the above, a wiring substrate 1 of the present embodiment is manufactured.

As shown in FIG. 8, in the wiring substrate 1 of the present embodiment, the interposer 5 is arranged in the opening portion 40a provided in the center portion of the reinforcing plate 41. The stepped portion 40x is provided like a ring on the lower part of the side surface of the opening portion 40a of the reinforcing plate 41, and the side surface of the opening portion 40a is processed into a stepped shape. That is, a diameter of the lower part of the opening portion 40a of the reinforcing plate 41 is set larger than a diameter of the upper part thereof.

In the present embodiment, the reinforcing plate 41 is formed of the copper plate 40. But various materials such as a metal plate except the copper plate, a silicon substrate, a ceramic substrate, and the like can be employed if such material can reinforce the rigidity of the interposer 5.

Then, the resin portion 60 is filled in the space between the side surface of the interposer 5 and the side surface of the opening portion 40a of the reinforcing plate 41. The resin portion 60 is formed to extend along the lower surface of the reinforcing plate 41. Accordingly, the interposer 5 and the reinforcing plate 41 are joined/coupled by the resin portion 60, and are formed integrally. A thickness of the reinforcing plate 41 corresponds to a thickness of the interposer 5. As a result, the wiring substrate 1 whose upper and lower surface sides are made flat is constructed by the interposer 5 and the reinforcing plate 41.

The interposer 5 is made thin type such that the thickness thereof is about 200 μm, and the rigidity of the interposer 5 is relatively weak as a single body. Therefore, in the present embodiment, the rigidity of the interposer 5 is reinforces by coupling the frame-shaped reinforcing plate 41 to the periphery of the interposer 5 by the resin portion 60 to prevent occurrence of a warp (see the reduced plan view in FIG. 8).

In the interposer 5, the through holes TH passing through in the thickness direction are provided in the silicon substrate 10. The insulating layer 12 is formed on the inner surfaces of the through holes TH and both surfaces sides of the silicon substrate 10. The through electrode 14 is filled in the through holes TH in the silicon substrate 10 respectively. The first wiring layers 20 connected mutually via the through electrodes 14 are formed on both surfaces sides of the silicon substrate 10 respectively.

The interlayer insulating layer 30 in which the via holes VH each reaching the first wiring layer 20 are provided is formed on the upper surface side of the silicon substrate 10. The second wiring layers 22 connected to the first wiring layers 20 via the via holes VH (via conductor) are formed on the interlayer insulating layer 30. Also, the solder resist 35 in which the opening portions 35a are provided on the connection portions of the second wiring layers 22 is formed, and the contact layers 25 are formed in the opening portions 35a. The solder bumps 28 are provided in the contact layers 25 on the second wiring layers 22.

In this manner, in the interposer 5 according to the present embodiment, the first wiring layers 20 connected mutually via the through electrodes 14 are formed on both surface sides of the silicon substrate 10 respectively. The multilayer wiring layer ML containing the first wiring layers 20 is formed on the upper surface side of the silicon substrate 10.

Also, the interlayer insulating layer 30 in which the first via holes VH1 reaching the first wiring layers 20 of the interposer 5 are provided is formed under the interposer 5 and the reinforcing plate 41. The second wiring layers 22 connected to the first wiring layers 20 of the interposer 5 via the first via holes VH1 (via conductor) are formed under the interlayer insulating layer 30. The second interlayer insulating layer 32 in which the second via holes VH2 reaching the second wiring layers 22 are provided is formed under the second wiring layers 22.

The third wiring layers 24 connected to the second wiring layers 22 via the second via holes VH2 (via conductor) are formed under the second interlayer insulating layer 32. Also, the solder resist 65 in which the opening portions 65a are provided under the connection portions of the third wiring layers 24 is formed. The external connection terminals 26 using the solder ball, or the like are provided onto the connection portions of the third wiring layers 24.

In this manner, the build-up wiring layer BL (the second and third wiring layers 22, 24, and the first and second interlayer insulating layers 30, 32) connected to the first wiring layers 20 is formed under the interposer 5. In the present embodiment, the two-layered build-up wiring layer BL (multilayer wiring layer) is illustrated as the lower wiring layer.

The build-up wiring layer BL functions as the fan-out wiring that draws around the first wiring layers 20 of the interposer 5 to the outside and expands the wiring pitch of the first wiring layers 20. The external connection terminals 26 are arranged in the outer area of the wiring substrate 1.

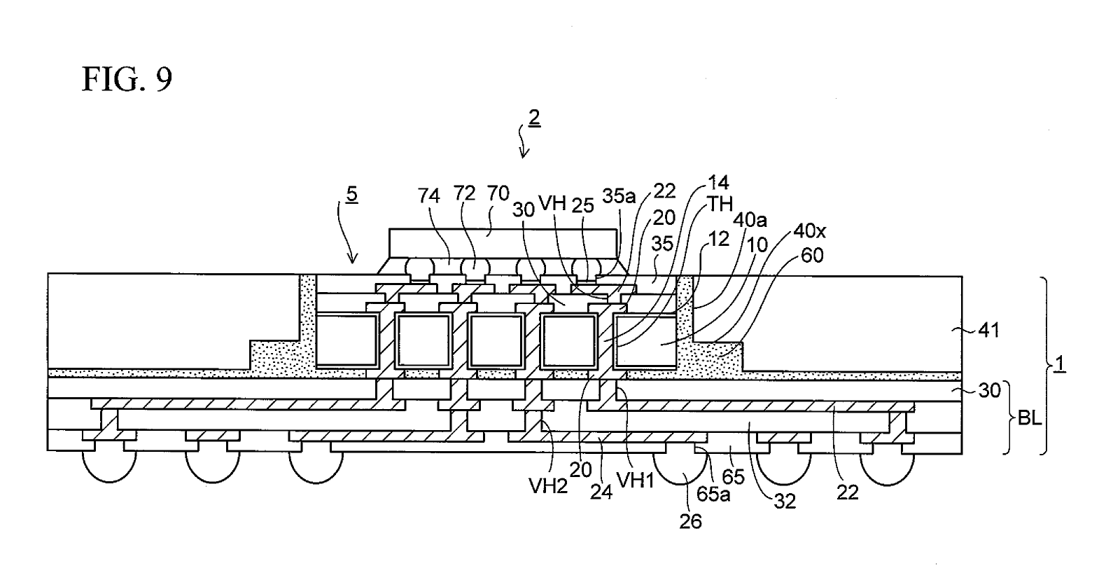

In FIG. 9, an electronic component device 2 constructed by mounting a semiconductor chip (LSI chip) on the wiring substrate 1 in FIG. 8 is shown. The solder bumps of a semiconductor chip 70 are arranged on the solder bumps 28 of the interposer 5 of the wiring substrate 1 in FIG. 8, and the semiconductor chip 70 is flip-chip connected to the interposer 5 by applying the reflow-heating.

Accordingly, as shown in FIG. 9, the solder bumps 28 of the interposer 5 of the wiring substrate 1 and the solder bumps of the semiconductor chip 70 are fused together, and thus bump electrodes 72 are formed. Thereby, the semiconductor chip 70 is connected electrically to the second wiring layers 22 of the interposer 5 of the wiring substrate 1 by the bump electrodes 72. As respective bumps of the interposer 5 and the semiconductor chip 70, various metals can be employed in addition to the solder.

Also, an underfill resin 74 is filled in a space under the semiconductor chip 70. Then, the underfill resin 74 is cured by applying a heat treatment.

With the above, the electronic component device 2 of the present embodiment is constructed.

At this time, during the solder-reflow applied to flip-chip connect the semiconductor chip 70 to the interposer 5 and during the heat treatment of the underfill resin 74, a thermal stress is ready to occur due to a difference in coefficient of thermal expansion between the semiconductor chip 70, the underfill resin 74, and the interposer 5.

However, in the present embodiment, even though such thermal stress occurs in mounting the semiconductor chip 70, the interposer 5 is reinforced with the reinforcing plate 41. Therefore, the interposer 5 can withstand the thermal stress and such a situation can be prevented that a warp of the interposer 5 occurs.

As a result, yield and reliability of the electronic component device 2 can be improved.

In the electronic component device 2 of the present embodiment, the pitch is transformed such that the bump pitch of the semiconductor chip 70 is expanded in order by the interposer 5 and the build-up wiring layer BL (fan-out wiring). Then, the external connection terminals 26 of the wiring substrate 1 are connected electrically to the motherboard (mounting substrate).

In this case, the semiconductor chip 70 is illustrated as the electronic component. But various the electronic components such as a capacitor, and the like may be mounted. Also, as the mounting (connecting) system of the electronic component, other systems except the flip-chip connection may be employed.

Also, a mode in which the build-up wiring layer BL is omitted may be employed. In such case, an external device is connected electrically to the first wiring layers 20 on the lower surface side of the interposer 5.

What is claimed is:

1. A wiring substrate, comprising:
a frame-shaped reinforcing plate in which an opening portion is provided in a center portion;
an interposer arranged in the opening portion of the reinforcing plate, and having such a structure that a wiring layer connected mutually via a through electrode is formed on both surface sides of a substrate respectively;
a resin portion filled between a side surface of the interposer and a side surface of the opening portion of the reinforcing plate, and coupling the interposer and the reinforcing plate; and
an n-layered (n is an integer of 1 or more) lower wiring layer formed under the interposer and the reinforcing plate, and connected to the wiring layer on the lower surface side of the interposer to extend from the interposer to an outer area.

2. A wiring substrate according to claim 1, wherein the substrate of the interposer is a silicon substrate or a ceramic substrate.

3. A wiring substrate according to claim 1, wherein a wiring pitch of the lower wiring layer is set wider than a wiring pitch of the wiring layer provided to the interposer.

4. A wiring substrate according to claim 1, wherein a diameter of a lower part of the opening portion in the reinforcing plate is set larger than a diameter of an upper part of the opening portion, and a side surface of the opening portion is formed like a stepped shape.

5. A wiring substrate according to claim 1, wherein the reinforcing plate is made of copper, silicon, or ceramic.

6. A wiring substrate according to claim 1, wherein a thickness of the reinforcing plate corresponds to a thickness of the interposer.

7. An electronic component device, comprising:
the wiring substrate set forth in claims 1; and
an electronic component mounted to be connected to the wiring layer of uppermost in the interposer of the wiring substrate.

8. An electronic component device according to claim 7, wherein the electronic component is a semiconductor chip, and the semiconductor chip is flip-chip connected to the wiring layer.
